(19) United States
(12) Patent Application Publication
(10) Pub. No.: US 2005/0239287 A1
(43) Pub. Date: Oct. 27, 2005

(54) Silicide formation using a metal-organic chemical vapor deposited capping layer

(76) Inventors: Mei-Yun Wang, Hsin-Chu (TW); Chih-Wei Chang, Hsin-Chu (TW); Cheng-Tung Lin, Jhudong Township (TW); Chii-Ming Wu, Taipei (TW); Shau-Lin Shue, Hsinchu (TW)

Correspondence Address: DUANE MORRIS LLP;IP DEPARTMENT (TSMC), 4200 ONE LIBERTY PLACE, PHILADELPHIA, PA, 19103-7396, US

(21) Appl. No.: 10/742,202

(22) Filed: Dec. 18, 2003

Related U.S. Application Data
(60) Provisional application No. 60/508,788, filed on Oct. 3, 2003.

(51) Int. Cl. H01L 21/3205

(52) U.S. Cl. 438/682; 438/683; 438/592

(57) ABSTRACT

A self-aligned silicide method for integrated circuit and semiconductor device fabrication wherein a metal layer is formed over one or more silicon regions of a substrate and a barrier metal layer is formed over the metal layer using a chemical vapor deposition process. The temperature at which the chemical vapor deposition process is performed causes the metal layer to react with the one or more silicon regions of the substrate to form a metal-silicide film over each of the silicon regions.

This application claims the benefit of U.S. Provisional Application No. 60/508,788, filed Oct. 3, 2003, the entirety of which is hereby incorporated by reference herein.

### BACKGROUND OF THE INVENTION

1. Field of the Invention

The invention relates to a salicide process for integrated circuit and semiconductor device fabrication. More particularly, the invention relates to a salicide process for fabricating metal interconnects and contact vias, wherein a silicide film is fabricated during the deposition of a capping or barrier metal layer by a chemical vapor deposition process.

2. Background of the Invention

Self-aligned silicide (salicide) technology is required in modern integrated circuit and semiconductor device fabrication to lower the resistance of polysilicon gates, sources and drains to reduce RC delay, i.e., the gate speed performance index wherein less delay produces increased gate speed performance.

There are a number of known silicide technologies, one of which is nickel silicide (NiSi). NiSi appears to have good utility for very narrow line polysilicon gates because it provides better sheet resistance (Rs) for narrow line polysilicon gates, less junction leakage, less silicon (Si) consumption, and can even improve the drive current (Idsat) of an NFET or PFET.

Existing salicide processes typically require two steps to fabricate a metal silicide film. The first step involves sequentially depositing a metal layer and a capping or barrier metal layer onto the substrate having the semiconductor device or devices formed thereon. The metal layer is typically deposited using a sputtering process and the capping metal layer is typically deposited using a physical vapor deposition (PVD) process. The second step involves rapid thermal annealing (RTA) the substrate to transform the portions of the metal layer overlying the silicon and polysilicon regions of the substrate to a metal silicide film. The unreacted portions of the metal and capping layers are then removed by etching.

The above salicide process is relatively expensive because it requires two steps to fabricate the metal silicide film, and the relatively thick PVD-generated capping metal layer requires a greater acid expense. In addition, the atoms of the capping layer diffuse into the silicide metal or Si/poly substrate during the annealing process, which causes undesirable reactions and phases that can degrade electrical performance of the semiconductor devices.

Accordingly, an improved salicide process is needed which overcomes the above-described disadvantages.

### SUMMARY OF THE INVENTION

A first aspect of the invention is a silicide method for integrated circuit and semiconductor device fabrication. The method comprises: providing a substrate having at least one silicon region; forming a layer of metal over the at least one silicon region of the substrate; and chemical vapor depositing a barrier metal layer over the metal layer; wherein the chemical vapor depositing step causes the metal layer to react with the at least one silicon region of the substrate to form a metal-silicide film thereover.

A second aspect of the invention is a method of fabricating a metal-silicide film. The method comprises: forming a layer of metal over at least one silicon region of a substrate; and chemical vapor depositing a barrier metal layer over the metal layer, the chemical vapor depositing step causing the metal layer to react with the at least one silicon region of the substrate to form the metal-silicide film thereover.

### BRIEF DESCRIPTION OF THE DRAWINGS

FIGS. 1A-1G are sectional views showing the steps of the self-aligned silicide process of the invention.

### DETAILED DESCRIPTION OF THE INVENTION

The present invention is a self-aligned silicide process (salicide) for reducing the resistance of the gate electrode and source/drain regions, wherein a metal silicide film is fabricated during the deposition of a capping or barrier metal layer using a chemical vapor deposition process (CVD) with high temperature processing as compared with PVD. In the present invention, the temperatures utilized during the CVD process to fabricate the capping layer, in-situ anneals the underlying metal layer to form the metal silicide film. The salicide process of the invention is especially useful for 90 nanometer and smaller gate technology, and may be extended to other applications of salicidation, by selecting appropriate CVD processing parameters.

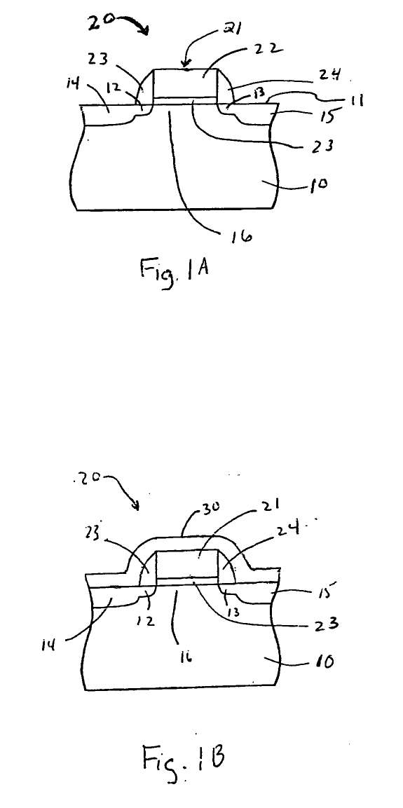

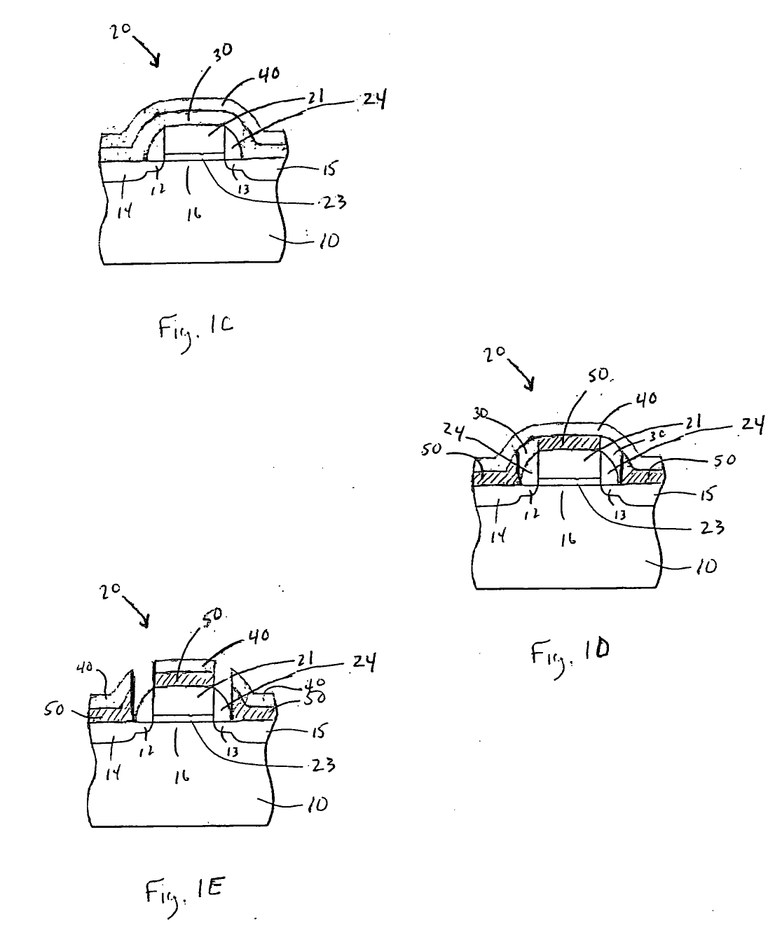

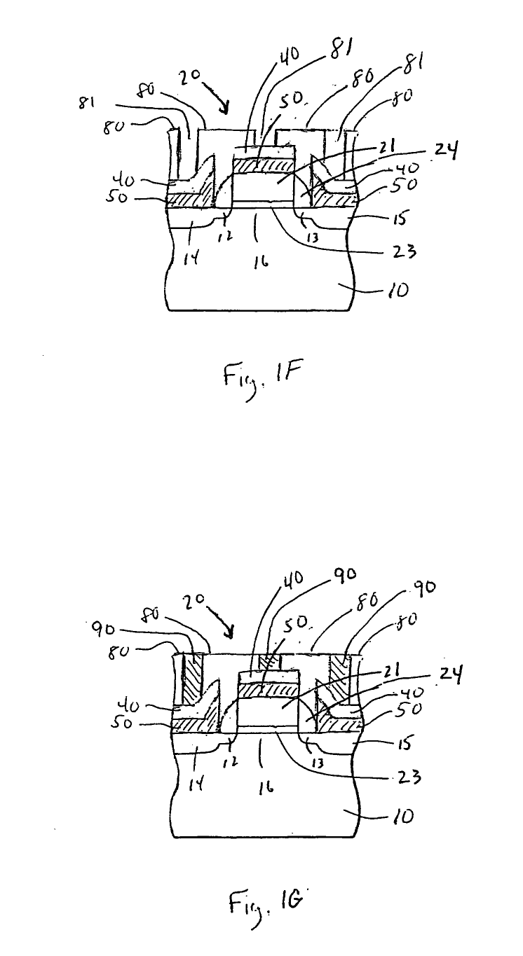

Referring now to FIG. 1A, there is shown a sectional view of a semiconductor transistor 20. The transistor 20 is formed on a silicon semiconductor substrate 10, composed, for example, of monocrystalline silicon. The transistor 20 comprises a gate 21 formed by a gate electrode 22 and a gate oxide 23 that dielectrically isolates the gate electrode from the substrate 10. The gate 21 is fabricated by forming the gate oxide film 22 over a first surface 11 of the substrate 10 using, for example, a conventional thermal oxidation process. The gate electrode 22 is then formed conventionally over the gate oxide film 22 from a conductive polycrystalline silicon or other conductive material. A spacer 24 may extend laterally outward from each of the sidewall surfaces of the gate 21. The spacers 24 may be conventionally formed, for example, from a nitride material. The substrate 10 includes an active region which receives dopants which are self-aligned to the sidewall surfaces of the gate 21 and the spacers 24. The dopants may be those which comprise the source/drain dopants as well as the LDD dopants. More specifically, the active region may include lightly doped source 12 and drain 13 regions which are self-aligned to the sidewalls of the gate 21, and heavily doped source 14 and drain 15 regions which are self-aligned to the sidewalls of the spacers 24. The lightly doped source 12 and drain 13 regions and the heavily doped source 14 and drain 15 regions may be formed in the substrate 10 using conventional methods. A channel 16 region is defined between the lightly doped source 12 and drain 13 regions.

The salicide process of the present invention commences with a pre-salicidation native oxide removal step. Native oxide removal may be accomplished by dipping the substrate 10 of FIG. 1A in an etchant, such as hydrofluoric acid. The etchant removes any native oxide (e.g. silicon dioxide) on the silicon surfaces of the substrate 10.

In FIG. 1B, a layer 30 of metal is conformally formed over the substrate 10 with or without in-situ dry cleaning which may include both physical bombardment and chemical reaction for native oxide removal. The metal layer 30 may be composed of a metal or combination of metals including, without limitation, Ni, Co, Ti, Pt, Mo, V, Pd, and Ta and formed using any conventional metal deposition technique, such as sputtering. The metal layer 30 is typically deposited to a thickness of between about 1 and 60 nanometers.

In FIG. 1C, a capping or barrier metal layer 40 is conformally formed over the substrate 10 using a CVD process, which utilizes metal-organic source materials, such as tetrakis dimethyl amino titanium (TDMAT) or tetrakis diethyl amino titanium (TDEAT), or other types of metal-organic source materials. In the present invention, the capping metal layer 40 may be a TiN, Ti, or other film used in PVD, which can be formed by CVD. The capping layer 40 may be also use alternate barrier metals containing other transition metals, such as Ta, WN, and TaN. Such capping layers can also be fabricated by CVD using the appropriate source materials.

The deposition temperature utilized during the CVD process is selected to in-situ anneal the underlying metal layer 30, thereby causing the metal layer 30 to react with underlying silicon portions to form a metal silicide film 50 and therefore, must be within the temperature range for metal silicide formation. In the Ni metal layer 30 and TiN cap layer 40 embodiment, the CVD of the TiN cap layer 40 may be performed in a CVD TiN chamber, which is set to a temperature within the 280° C. to 650° C. temperature range for nickel silicide (NiSi) formation, e.g., 405° C. The chamber pressure may be maintained at about 5 Torr and the source material flow rate (using a TDMAT source material) may be maintained at about 55 sccm. The cap layer 40 is typically deposited to a thickness of up to about 10 nanometers. The cap layer 40 prevents oxidation of the metal silicide film 50 formed thereunder. The stable CVD cap layer 40 also prevents reaction with both the metal layer 30 and the silicon to inhibit undesirable phase formations.

As shown in FIG. 1D, the CVD process transforms the metal layer 30, e.g. Ni, overlying the source 14 and drain 15 regions of the silicon substrate 10 and overlying the polysilicon gate 21 to a metal silicide film 50, e.g., nickel silicide (NiSi). As can be seen in FIG. 1D, the metal layer 30 atoms diffuse into the source/drain regions 14/15 and the polysilicon gate 21. The portions of the metal layer 30 overlying the nitride spacers 24 remain unreacted after CVD.

In FIG. 1E, the process may be completed by removing the capping layer 40 and the unreacted portions of the metal layer 30 from the substrate 10 using any conventional etching process, such as wet etching with a conventional silicide selective etch (SPM) solution, which typically comprises a H₂SO₄/H₂O₂ (within H₂O) mixture. The thinner CVD cap layer 40, as compared with a conventionally formed PVD cap layer, saves acid usage during this fabrication process. After selectively removing un-reacted metal layer 30 and capping layer 40, an optional second annealing process may be performed.

After completing the process of the invention, contacts to the gate 21, and the source 14 and drain 15 regions may be formed using conventional methods. For example, the contacts may be formed by depositing a dielectric layer 80 conformally over the substrate 10 and etching contact openings 81 in the dielectric layer 80 above the gate 21, and the source 14 and drain 15 regions as shown in FIG. 1F. The contact openings 81 may then be filled with a conductive material 82 to complete the contacts 90 as shown in FIG. 1G.

While the foregoing invention has been described with reference to the above embodiments, various modifications and changes can be made without departing from the spirit of the invention. Accordingly, all such modifications and changes are considered to be within the scope of the appended claims.

1. A silicide method for integrated circuit and semiconductor device fabrication, the method comprising the steps of:
providing a substrate having at least one silicon region;
forming a layer of metal over the at least one silicon region of the substrate; and
chemical vapor depositing a barrier metal layer over the metal layer,
wherein the chemical vapor depositing step causes the metal layer to react with the at least one silicon region of the substrate to form a metal-silicide film thereover.

2. The method according to claim 1, wherein the metal layer comprises nickel.

3. The method according to claim 2, wherein the barrier metal layer comprises titanium nitride.

4. The method according to claim 3, wherein the metal-silicide film comprises nickel silicide

5. The method according to claim 1, wherein the barrier metal layer comprises titanium nitride.

6. The method according to claim 1, wherein the metal-silicide film comprises nickel silicide

7. The method according to claim 1, wherein the metal-silicide film is formed within a predetermined temperature range, the chemical vapor depositing step being performed at a temperature that is within the predetermined temperature range.

8. The method according to claim 1, wherein the chemical vapor depositing step is performed with a metal-organic source material.

9. The method according to claim 1, wherein the chemical vapor depositing step is performed at a temperature between 280° C. and 650° C.

10. A method of fabricating a metal-silicide film, the method comprising the steps of:
forming a layer of metal over at least one silicon region of a substrate; and
chemical vapor depositing a barrier metal layer over the metal layer, the chemical vapor depositing step causing the metal layer to react with the at least one silicon region of the substrate to form the metal-silicide film thereover.

11. The method according to claim 10, wherein the metal layer comprises nickel.

12. The method according to claim 11, wherein the barrier metal layer comprises titanium nitride.

13. The method according to claim 12, wherein the metal-silicide film comprises nickel silicide

14. The method according to claim 10, wherein the barrier metal layer comprises titanium nitride.

15. The method according to claim 10, wherein the metal-silicide film comprises nickel silicide

16. The method according to claim 10, wherein the metal-silicide film is formed within a predetermined temperature range, the chemical vapor depositing step being performed at a temperature that is within the predetermined temperature range.

17. The method according to claim 10, wherein the chemical vapor depositing step is performed with a metal-organic source material.

18. The method according to claim 10, wherein the chemical vapor depositing step is performed at a temperature between 280° C. and 650° C.
